(19) United States
(12) Patent Application Publication
(10) Pub. No.: US 2011/0121189 A1
(43) Pub. Date: May 26, 2011

(54) RADIATION DETECTOR

(75) Inventor: Yoshihiro OKADA, Kanagawa (JP)

(73) Assignee: FUJIFILM Corporation, Tokyo (JP)

(21) Appl. No.: 12/943,464

(22) Filed: Nov. 10, 2010

(30) Foreign Application Priority Data
Nov. 20, 2009 (JP) 2009-265196

(51) Int. Cl. G01T 1/24

(52) U.S. Cl. 250/370.08

(57) ABSTRACT

Scan lines, each disposed to plural pixel lines for each of the pixel lines in a row direction of plural pixels disposed in a matrix, that switch each TFT switch provided at respective pixels in the plural pixel lines. Plural signal lines are each disposed to each of the pixel lines in the row direction of the matrix array. In each of the pixel lines in the row direction, respective signal line is connected to different TFT switch from the TFT switches that are connected to the same respective scan line, and charges accumulated in charge storage capacitors is read out according to the states of the TFT switches. The pixels or the signal lines at a subset of the pixel lines in one direction are disposed shifted in the one direction, such that the signal lines are disposed between pixels of the pixel lines.

### CROSS-REFERENCE TO RELATED APPLICATION

This application claims priority under 35 USC 119 from Japanese Patent Application No. 2009-265196, filed on Nov. 20, 2009, the disclosure of which is incorporated by reference herein.

### BACKGROUND OF THE INVENTION

1. Field of the Invention

The present invention relates to a radiation detector. The present invention particularly relates to a radiation detector that accumulates charges generated by irradiation of radiation onto plural pixels disposed in a matrix, and that detects the accumulated charge amounts of the charges as information that represents an image.

2. Description of the Related Art

In recent years, radiation imaging devices using radiation detectors such as FPDs (flat panel detectors) in which x-ray sensitive layers are disposed on TFT (thin film transistor) active matrix substrates, and that can convert x-ray information directly to digital data, and the like, have been put into practice. As compared with a conventional imaging plate, an image can be confirmed immediately at an FPD. Further, the FPD has the advantage that video images as well can be confirmed. Therefore, the popularization of FPDs has advanced rapidly.

Various types of radiation detector are proposed. For example, there is a direct-conversion-type radiation detector that converts radiation directly into charges in a semiconductor layer, and accumulates the charges. Moreover, there is an indirect-conversion-type radiation detector that once converts radiation into light at a scintillator of CsI:Tl, GOS (Gd2O2S:Tb), or the like, and, at semiconductor layer, converts the converted light into charges and accumulates the charges.

In radiation detector, for example, plural scan lines and plural signal lines are disposed so as to intersect with each other, and charge storage capacitors and TFT switches are provided at each of the intersections between the scan lines and the signal lines. Further, in radiation detector, a semiconductor layer is also provided to cover the charge storage capacitors, and the TFT switches are provided at each of the intersections. When radiation imaging apparatuses using such radiation detector capture radiation images, during irradiation of X-rays, an OFF signal is output to each of the scan lines, and each of the TFT switches is switched OFF. Accordingly, the charges generated in the semiconductor layer are accumulated in each of the charge storage capacitors. Then, when reading out an image from the radiation imaging apparatus, an ON signal is output to each scan line one at a time in sequence, the charges accumulated at each of the charge storage capacitors is read out as an electrical signal, and the read-out electrical signal is converted into digital data. The radiation imaging apparatus obtains radiation images according to the above procedures.

However, when radiation imaging apparatuses attempt to read out radiographic images successively from the radiation detector in order to obtain a video image, the number of frames of radiation image read-out per second (the frame rate) is large. Further, in a radiation imaging apparatus, the scanning time for outputting an ON signal to a single scanning line, and for reading out the electrical signal, also gets smaller as the number of scan lines of the radiation detector increases.

The scan time 1H can be derived according to expression (1) below, where the frame rate is denoted by FR, and the number of scan lines of the radiation detector is denoted by Gn.

1H=1/FR/Gn (1)

For example, when the frame rate FR is 60, and the number of scan lines Gn is 1000 lines, then the scan time 1H is 16.7 μs.

If a TFT active matrix substrate is used as a liquid crystal display (LCD), the scan time 1H can be used entirely as time for reading in data. This means that 16.7 μs is a sufficient time.

However, if a TFT active matrix substrate is used as a detection element that captures an image, then in order to perform noise reduction (namely, when used as a detection element for medical radiographic image capture that requires low-noise imaging), not all of the scan time 1H can be allocated to a charge read-out period, since after amplifying the electrical signal of charge that has been accumulated in each of the charge storage capacitors, and is converted into digital data in an A/D (analogue/digital) conversion unit, and correction processing and the like, is performed to the converted digital data. This makes it difficult to image video images of high frame rate.

Japanese Patent Application Laid-Open (JP-A) No. 2003-264273 discloses a technology to address this issue, enabling imaging of video images of high frame rate. In this technology, the image receiving face of the radiation detector is divided into plural pixel areas, read-out devices are provided for each of the pixel areas, and image read-out is performed for each of the pixel areas.

However, in the technology recited in JP-A No. 2003-264273, the image receiving face is divided into plural pixel areas and pixels are read out in series from each of the pixel areas. Thus, although this technique may increase the speed of pixel read-out overall, they do not increase the speed of pixel read-out for a single pixel area.

### SUMMARY OF THE INVENTION

The present invention provides a radiation detector that can raise the speed of reading out the pixels and can suppress differences in line capacitance between signal lines.

A first aspect of the present invention is a radiation detector including: a plurality of pixels disposed in a matrix, along a first direction and a second direction intersecting with the first direction, each pixel accumulates charges generated by the irradiation of radiation, and includes a switching element for reading out the accumulated charges; scan lines that switch each of the switching elements, each scan line disposed corresponding to a plurality of pixel lines in the first direction, and connected to each of the switching element provided at the respective pixels in the plurality of pixel lines; and signal lines, in which a plurality of signal lines are disposed corresponding to each of the pixel lines in the second direction, each signal line of the signal lines disposed corresponding to the same pixel line connected to a different switching element of the switching elements connected to the same scan line, and charges accumulated in the pixels flowing through the signal lines according to switching state of the switching elements, wherein at least one of the pixel lines and the signal lines is disposed shifted in the first direction at a subset of the pixel lines in the first direction, such that the plurality of signal lines provided for each pixel line in the second direction are disposed between pixels of the pixel lines in the first direction.

The radiation detector of the first aspect of the present invention accumulates charges generated by irradiation of radiation which are subjects for detection. In the radiation detector of the first aspect of the present invention, plural pixels provided with switching elements for reading out the accumulated charges are disposed in a matrix, along a first direction and a second direction intersecting with the first direction.

In the first aspect, scan lines, that switches each of the switching elements, are each disposed to plural pixel lines in the first direction of the plural pixels disposed in the matrix array, and are each connected to each of the switching elements provided to the respective pixels in the plural pixel lines. The signal lines, that flows there through the charges accumulated in the pixels according to the switching state of the switching elements, are each disposed to each of the pixel lines in the second direction of the matrix array, and are each connected to a different switching element from the switching elements that are connected to the same respective scan line in each of the pixel lines in the second direction.

In the present invention, either or both of the pixels and the signal lines is disposed shifted in the one direction at a subset of the pixel lines in the one direction, such that the plural signal lines provided for each pixel line in the intersecting direction are disposed between pixels of some of the pixel lines in the one direction.

According to the first aspect of the present invention, switching elements for the pixels in the pixel lines in the first direction can be switched by plural pixel lines at a time in the above manner, and the charge accumulated in each of the pixel can be read out at plural lines at a time. Therefore, the radiation detector of the first aspect can consequently raise the image read-out speed.

Further, according to the present invention, at least one of the pixels and the signal lines is shifted in the one direction at the subset of the pixel lines in the one direction, and the plural signal lines provided for each pixel line in the intersecting direction are located between the pixels of some of the pixel lines in the one direction. Therefore, the first aspect of the present invention can suppress differences in line capacitance between the signal lines.

A second aspect of the present invention is a radiation detector including: a plurality of pixels disposed in a matrix, along a first direction and a second direction intersecting with the first direction, each pixel accumulates charges generated by the irradiation of radiation, and includes a switching element for reading out the accumulated charges; scan lines that switch each of the switching elements, one scan line being disposed corresponding to each pixel line in the first direction, the scan lines being connected to each of the switching elements provided to each pixel in the corresponding of pixel line; connection lines, each electrically connecting a specific number of the scan lines; and signal lines, in which a plurality of signal lines are disposed corresponding to each of the pixel lines in the second direction, each signal line of the signal lines disposed corresponding to the same pixel line being connected to a different switching elements of the switching elements connected to the specific number of scan lines electrically connected by the same connection line, and the charges accumulated at the pixels flow through the signal lines according to the switching state of the switching elements, wherein at least one of the pixel lines and the signal lines is disposed shifted in the first direction at a subset of the pixel lines in the first direction, such that the plurality of signal lines provided for each pixel line in the second direction are disposed between pixels of the pixel lines in the first direction.

In the radiation detector of the second aspect, pixels that accumulate charge generated by irradiation with radiation are provided with switching elements for reading out the accumulate charge, and the pixels are disposed in a matrix, along a first direction and a second direction intersecting with the first direction.

Scan lines, that switches the switching elements, are each disposed to each of the pixel lines in the first direction of the plural pixels disposed in the matrix array, and are each connected to each of the switching elements provided to each the pixels in the respective pixel line. A specific number of these scan lines are electrically connected together by respective connection lines. Plural signal lines are also disposed to each of the pixel lines in the intersecting direction of the matrix array. The respective signal lines for each of the pixel lines in the second direction are connected to a different switching element from the switching elements that are connected to the specific number of respective scan lines that have been electrically connected together by the same connection line. Further, the signal lines flows there through the charges accumulated in the pixels according to the switching state of the switching elements.

In the second aspect, either or both of the pixels and the signal lines is disposed shifted in the one direction at a subset of the pixel lines in the one direction, such that the plural signal lines provided for each pixel line in the intersecting direction are disposed between pixels of some of the pixel lines in the one direction.

Accordingly, the second aspect can switch the switching elements of each pixel of the pixel lines in the first direction, by plural lines of switch elements at a time, since a specific number of scan lines are electrically connected via the connection lines. Further, the second aspect can read out the charges accumulated in each pixel, from plural pixel lines at a time, via the signal lines. Therefore, the second aspect of the present invention can consequently raise the pixel read-out speed.

Further, according to the second aspect, at least one of the pixels and the signal lines is shifted in the one direction at the subset of the pixel lines in the one direction, and the plural signal lines provided for each pixel line in the intersecting direction are located between the pixels of some of the pixel lines in the one direction. Therefore, the second aspect of the present invention can suppress differences in line capacitance between the signal lines.

A third aspect of the present invention, in the first aspect, the scan lines may be provided such that one scan line is provided for each two pixel lines in the first direction, disposed between the two respective pixel lines; and each of the switching elements may be provided at the scan line side of the corresponding pixel.

A fourth aspect of the present invention, in the above described aspects, two of the signal lines may be provided for each of the pixel lines in the second direction, with one of the two signal lines may be disposed so as to pass through a central portion of the pixels with equally-spaced intervals.

A fifth aspect of the present invention, in the above described aspects, the signal lines may be provided with equally-spaced intervals; and at each pixel line in the first direction, the pixels of the pixel line in the first direction may be disposed shifted in the first direction by an amount corresponding to the spacing of the signal lines in the first direction.

A sixth aspect of the present invention, in the above described aspects, the pixels may be further provided with a collection electrode that collects generated charges, and the collection electrode may be provided with a slit at a position where the signal line is disposed.

A seventh aspect of the present invention, in the sixth aspect, the pixels may be further provided with a charge accumulation portion that accumulates the collected charges, and the charge accumulation portion and the switching elements may be electrically connected via the collection electrodes.

An eighth aspect of the present invention, in the seventh aspect, the charge accumulation portions may be configured with two facing electrodes, and may further include auxiliary capacitor lines, each disposed to a plurality of pixel lines in the first direction, each connected to one of the electrodes of the charge accumulation portion provided at each of the pixels of the plurality of pixel lines.

A ninth aspect of the present invention, in the seventh aspect, the charge accumulation portion may be configured with two facing electrodes, and may further include auxiliary capacitor lines, each disposed corresponding to each of the pixel lines in the second direction alongside the signal lines, and each connected to one of the electrodes of the charge accumulation portions provided at each of the pixels in each of the pixel lines in the second direction.

A tenth aspect of the present invention, in the eighth aspect, the signal lines and the auxiliary capacitor lines may be formed in different wiring layers.

Accordingly, the present invention can provide a radiation detector that can raise the speed of reading out the pixels and can suppress differences in line capacitance between signal lines.

### BRIEF DESCRIPTION OF THE DRAWINGS

Exemplary embodiments of the present invention will be described in detail based on the following figures, wherein:

FIG. 1 is a structural diagram illustrating the overall structure of a radiographic imaging device according to a first exemplary embodiment of the present invention;

FIG. 2 is a plan view illustrating the structure of a radiation detector according to the first exemplary embodiment;

FIG. 3 is a cross-sectional view of the radiation detector according to the first exemplary embodiment;

FIG. 4 is a structural diagram illustrating the overall structure of a radiographic imaging device according to a second exemplary embodiment of the present invention;

FIG. 5 is a plan view illustrating the structure of a radiation detector according to the second exemplary embodiment;

FIG. 6 is a cross-sectional view of the radiation detector according to the second exemplary embodiment;

FIG. 7 is a structural diagram illustrating the structure of a radiation detector according to a third exemplary embodiment;

FIG. 8 is a cross-sectional view of the radiation detector according to the third exemplary embodiment of the present invention;

FIG. 9 is a plan view illustrating the structure of a radiation detector according to a fourth exemplary embodiment of the present invention;

FIG. 10 is a plan view illustrating the structure of a radiation detector according to a fifth exemplary embodiment of the present invention;

FIG. 11 is a cross-sectional view of the radiation detector according to the fifth exemplary embodiment;

FIG. 12 is a structural diagram illustrating the structure of a radiation detector according to a sixth exemplary embodiment of the present invention;

FIG. 13 is a plan view illustrating the structure of a radiation detector according to the sixth exemplary embodiment;

FIG. 14 is a structural diagram illustrating the structure of a radiation detector according to a seventh exemplary embodiment of the present invention;

FIG. 15 is a structural diagram illustrating the structure of a radiation detector according to an alternative exemplary embodiment of the present invention;

FIG. 16 is a structural diagram illustrating the structure of a radiation detector according to an alternative exemplary embodiment;

FIG. 17 is a structural diagram illustrating the structure of a radiation detector according to an alternative exemplary embodiment;

FIG. 18 is a plan view illustrating the structure of a radiation detector according to an alternative exemplary embodiment; and

FIG. 19 is a cross-sectional view of a radiation detector according to an alternative exemplary embodiment.

### DETAILED DESCRIPTION OF THE INVENTION

Herebelow, exemplary embodiments for carrying out the present invention are described with reference to the attached drawings.

### First Exemplary Embodiment

As a first exemplary embodiment, a case in which the present invention is applied to an indirect-conversion-type of radiation detector 10A, which temporarily converts radiation to light and converts the converted light to charges, is described.

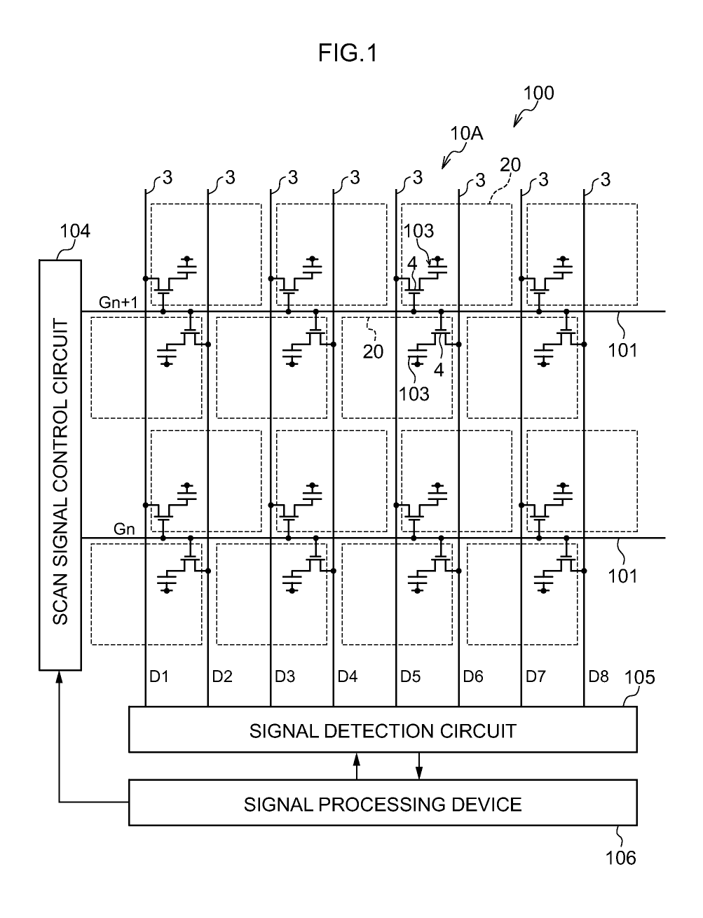

FIG. 1 illustrates the overall structure of a radiographic imaging device 100 that includes the radiation detector 10A according to the first exemplary embodiment.

As illustrated in FIG. 1, the radiographic imaging device 100 according to the present exemplary embodiment includes an indirect-conversion-type radiation detector 10A. Note that, a scintillator that converts radiation to light is not illustrated in FIG. 1.

The radiation detector 10A includes plural pixels 20 that are configured to include sensor portions 103 and TFT switches 4. The sensor portions 103 generate charges by illumination of light, and accumulate the generated charges. The TFT switches 4 read out the charges accumulated in the sensor portion 103.

The pixels 20 are disposed in one direction (the horizontal direction of FIG. 1, which is hereinafter referred to as “the row direction”) and in an intersecting direction relative to the row direction (the vertical direction in FIG. 1, which is hereinafter referred to as “the column direction”), forming a matrix. The pixels of the present exemplary embodiment are disposed with a subset of the row direction pixel lines in the matrix, being shifted in the row direction. In the radiation detector 10A according to the first exemplary embodiment, the pixels 20 are arranged with the pixels 20 of every second row direction pixel line being shifted in the row direction by half of a pixel width (half the pitch) of the row direction pixel lines.

Further, in the radiation detector 10A, scan lines 101 are provided one for each two row direction pixel lines in the matrix of the plural pixels 20, and is disposed between the two pixel lines. At each pixel 20, the TFT switch 4 is disposed at the side of the respective scan line 101. Each scan line 101 is connected to the TFT switches 4 provided in the pixels 20 of the two pixel lines, and switches these TFT switches 4.

Signal lines 3 are provided, with equally-spaced intervals, two for each of the column direction pixel lines of the matrix of the plural pixels 20. The two signal lines 3, along a column direction pixel line, passes through the middle portion of the pixels 20 and between the pixels 20 for each row direction pixel line. In each row direction pixel line, the signal lines 3 are connected to different TFT switches 4 of the TFT switches 4 that are connected to the same scan line 101. Charges accumulated in charge storage capacitors 5 flow into the signal lines 3 in accordance with switching states of the TFT switches 4. Namely, the two signal lines 3 of the column direction pixel lines are each connected to different TFT switches 4 that are connected to the same scan lines 101. For each the signal line 3, a signal detection circuit 105 that detects electronic signal that has flown through the signal lines 3 is connected. For each the scan line 101, a scan signal control circuit 104 that outputs control signals for turning the TFT switches 40N and OFF to the scan lines 101, is connected.

The signal detection circuit 105 incorporates, for each signal line 3, an amplification circuit that amplifies the inputted electronic signals. The electronic signals inputted from the signal lines 3 are amplified by the amplification circuits, and are detected in the signal detection circuit 105. Therefore, the signal detection circuit 105 detects charge amounts accumulated in each of the charge storage capacitors 5 as information of pixels that represents an image.

A signal processing device 106 is connected to the signal detection circuit 105 and the scan signal control circuit 104. The signal processing device 106 applies predetermined processing, such as noise reduction and the like, to the electronic signals detected in the signal detection circuit 105. Further, the signal processing device 106 outputs control signals that indicates signal detection timings to the signal detection circuit 105, and outputs control signals that indicates scan signal output timings to the scan signal control circuit 104.

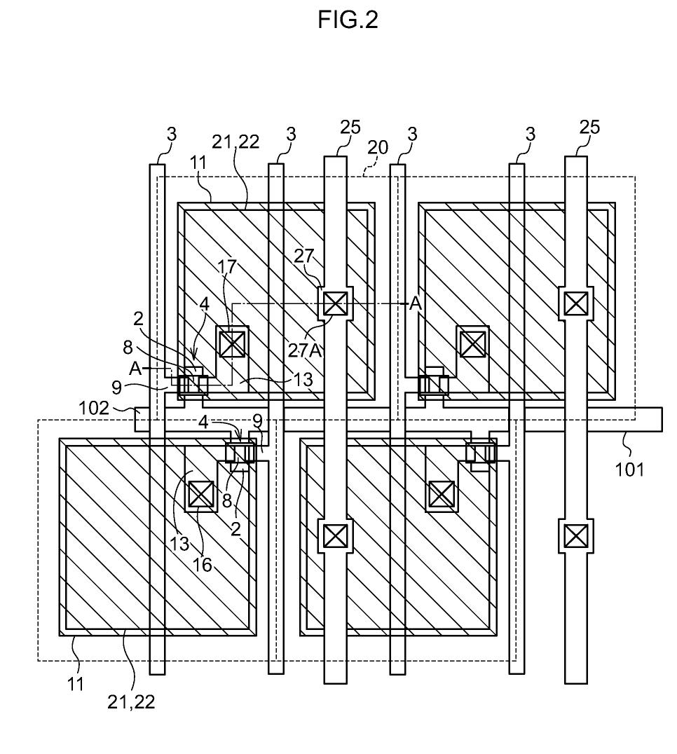

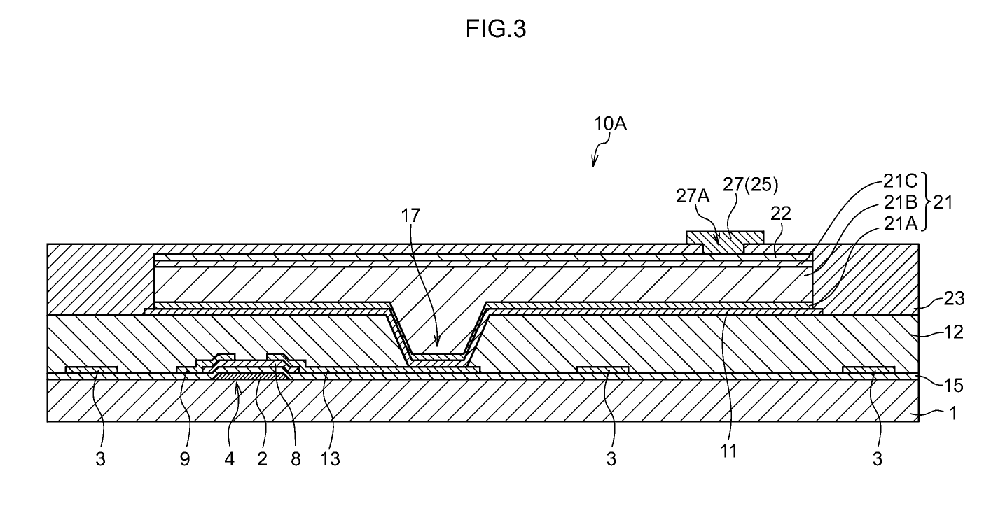

FIG. 2 shows a plan view illustrating the structure of the indirect-conversion-type radiation detector 10A according to the present exemplary embodiment. FIG. 3 shows a cross-sectional diagram along line A-A of FIG. 2.

As illustrated in FIG. 3, in the radiation detector 10A, the scan lines 101 (see FIG. 2) and gate electrodes 2 are formed on an insulating substrate 1, formed of alkaline-free glass or the like. The scan line 101 is connected with the gate electrode 2 (see FIG. 2). A wiring layer in which the scan line 101 and the gate electrodes 2 are formed (hereinafter this wiring layer may be referred to as “the first signal wiring layer”) is formed by using Al or Cu, or a layered film formed including Al or Cu. However, the material of the first signal wiring layer are not limited to these.

An insulating film 15 is formed on the entire surface on the first signal wiring layer. The region of the insulating film 15 that is positioned above the gate electrode 2 works as a gate insulating film of the TFT switch 4. The insulating film 15 is formed of, for example, SiN_{X} or the like. The insulating film 15 is formed by, for example, CVD (Chemical Vapor Deposition).

A semiconductor active layer 8 is formed at positions corresponding to the gate electrode 2 on the insulating film 15 in an island form. The semiconductor active layer 8 is the channel portion of the TFT switches 4, and is formed from, for example, an amorphous silicon film.

Source electrodes 9 and drain electrodes 13 are formed at the upper layer of the above-described layers. In the wiring layer in which the source electrodes 9 and the drain electrodes 13 are formed, signal lines 3 are formed together with the source electrodes 9 and the drain electrodes 13. The source electrodes 9 are connected to the signal lines 3 (see FIG. 2). The wiring layer in which the source electrodes 9, the drain electrodes 13 and the signal lines 3 are formed (hereinafter this wiring layer may be referred to as “the second signal wiring layer”) is formed by using Al or Cu, or a layered film formed including Al or Cu. However, the material of the second signal wiring layer are not limited to these. An impurity doped semiconductor layer (not illustrated), formed of amorphous silicon doped with impurities or the like, is formed between the source electrodes 9 and drain electrodes 13 and the semiconductor active layer 8. The TFT switches 4 for switching are configured by the above mentioned layers. Note that, in the TFT switches 4, based on the polarity of charges that are collected and accumulated by lower electrodes 11, described later, the source electrodes 9 and the drain electrodes 13 become opposite.

An interlayer insulating film 12 is formed covering the second signal wiring layer, over substantially the entire surface (substantially the whole region) where the pixels 20 are provided on the substrate 1. This interlayer insulating film 12 is formed of a photosensitive organic material with low permittivity (relative permittivity εᵣ=2 to 4) (for example, a positive-type photosensitive acrylic resin such as a material in which a naphthoquinone diazide-based positive-type light-sensitive photosensitivity agent is mixed into a base polymer formed of a copolymer of methacrylic acid and glycidyl methacrylate, or the like). The thickness of the interlayer insulating film 12 is 1 to 4 μm. In order to protect the TFT switches 4 and the signal lines 3, a TFT protection layer formed of, for example, SiNₓ or the like may be formed between the second signal wiring layer and the interlayer insulating film 12.

In the radiation detector 10A according to the present exemplary embodiment, capacitance of the metal layers that are disposed above and below the interlayer insulating film 12 is kept low by the interlayer insulating film 12. Further, generally, a material such as the above also functions as a flattening film, and also has the effect of flattening the steps of the lower layer. In the radiation detector 10A according to the present exemplary embodiment, contact holes 17 are formed in the interlayer insulating film 12 at positions opposing the drain electrodes 13.

The lower electrodes 11 of the sensor portions 103 are formed on the interlayer insulating film 12 so as to cover the pixel region and fill in the contact holes 17. The lower electrodes 11 are connected with the drain electrodes 13 of the TFT switches 4. The lower electrodes 11 may be made of any conductive material, if semiconductor layers 21 have a thickness of around 1 μm. Therefore, the lower electrodes 11 may be formed using a conductive metal such as Al, ITO or the like.

If the layer thickness of the semiconductor layers 21 is thin (around 0.2 to 0.5 μm), light may not be sufficiently absorbed by the semiconductor layers 21. Accordingly, in order to prevent an increase in leakage currents due to the illumination of light onto the TFT switches 4, it is preferable to form the lower electrodes 11 by an alloy or layered film with a light-blocking metal as a principal constituent.

The semiconductor layers 21, which function as photodiodes, are formed on the lower electrodes 11. In the present exemplary embodiment, PIN structure photodiode, in which an n⁺ layer, an i layer and a p⁺ layer are layered (n⁺ amorphous silicon, amorphous silicon, and p⁺ amorphous silicon), are employed as the semiconductor layers 21. Therefore, the semiconductor layers 21 of the present exemplary embodiment are formed by layering an n⁺ layer 21A, an i layer 21B and a p⁺ layer 21C, in this order from the lower layer. The i layer 21B generates charges (pairs of free electrons and free holes) when illuminated with light. The n⁺ layer 21A and the p⁺ layer 21C function as contact layers and electrically connect the lower electrodes 11 and upper electrodes 22 with the i layer 21B.

In the present exemplary embodiment, the lower electrodes 11 are formed wider than the semiconductor layers 21, and the light illumination side of the TFT switches 4 is covered by the semiconductor layers 21. Thus, in the present exemplary embodiment, a proportion of the area of the pixel region in which light may be detected (what is known as the fill factor) is large, and incidence of light onto the TFT switches 4 is suppressed.

The upper electrodes 22 are respectively individually formed on the semiconductor layers 21. A high light transmissive material such as, for example, ITO, IZO (indium zinc oxide) or the like is used for the upper electrodes 22. In the radiation detector 10A according to the present exemplary embodiment, the sensor portions 103 are configured by the upper electrodes 22, the semiconductor layers 21 and the lower electrodes 11.

An interlayer insulating film 23 is formed over the interlayer insulating film 12, the semiconductor layers 21 and the upper electrodes 22, so as to cover the semiconductor layers 21 with openings 27A at portions that correspond to the upper electrodes 22.

Above the interlayer insulating film 23, common electrode wiring 25 is formed by using Al or Cu, or a layered film formed including Al or Cu as a principal constituent. Contact pads 27 are formed on the common electrode wiring 25 near the openings 27A. The contact pads 27 are electrically connected with the upper electrodes 22 through the openings 27A in the interlayer insulating film 23.

On the radiation detector 10A formed in the above mentioned manner, a protective film is formed by an insulating material with low light absorption, if required. Further, a scintillator consisting of GOS or the like is adhered to the top surface of the protective film using an adhesive resin with low light absorption.

Next, operation of the radiographic imaging device 100 with the structure described above is described.

When the radiation detector 10A is irradiated with X-rays, the X-rays with which the radiation detector 10A has been irradiated are absorbed by the scintillator and converted into visible light. The radiation detector 10A may be irradiated with the X-rays from its front side or its back side. The semiconductor layers 21 of the sensor portions 103 placed in an array on the substrate 1 is illuminated with the light, that has been converted into visible light by the scintillator.

The semiconductor layers 21 are separated into each pixel unit and, are disposed in the radiation detector 10A. A predetermined bias voltage is applied to the semiconductor layers 21 from the upper electrodes 22 via the common electrode wiring 25. When the semiconductor layers 21 are illuminated with light, an electric charge is generated inside the semiconductor layers 21. For example, when the semiconductor layers 21 has a PIN structure in which an n⁺ layer, an i layer and a p⁺ layer are layered in this order from the bottom, a negative bias voltage is applied to the upper electrodes 22. When the film thickness of the i layer 21B is about 1 μm, the bias voltage applied to the upper electrodes 22 is about −5 V to −10 V.

When light is not illuminated in a state in which the bias voltage is applied to the semiconductor layers 21, a current of up to a few pA/mm² flows. When light is illuminated (1 μW/cm²) in the state in which the bias voltage is applied, a light current of several to tens of nA/mm² is generated. The generated charges are collected by the lower electrodes 11. The lower electrodes 11 are connected to the drain electrodes 13 of the TFT switches 4. The source electrodes 9 of the TFT switches 4 are connected to the signal lines 3. During image detection, a negative bias is applied to the gate electrodes 2 of the TFT switches 4. Consequently, the TFT switches 4 are held in off states, and the charges collected by the lower electrodes 11 are accumulated.

During image read-out, ON signals are outputted from the scan signal control circuit 104 to the scan lines 101 sequentially, one line at a time. The ON signals (+10 to +20 V) are applied to the gate electrodes 2 of the TFT switches 4 sequentially via the scan lines 101. Accordingly, the TFT switches 4 of the pixels 20 of two lines at a time, in the row direction of the matrix array of the plural pixels 20, are sequentially turned on. As a result, electronic signals corresponding to the charges accumulated at the lower electrodes 11 of the pixels 20 flow out into the signal lines 3, two lines at a time.

In the radiation detector 10A according to the first exemplary embodiment, there are two signal lines 3 provided for each respective pixel line in the column direction. Also, for each of the pixel lines in the column direction, the respective two signal lines 3 are connected to different TFT switches 4 from the TFT switches 4 that are connected to the same given scan line 101. Consequently, the electrical signals flowing out from the pixels 20 at two pixel lines at a time each flow out through different signal lines 3.

The signal detection circuit 105 detects, as information for each pixel in two lines worth configuring an image, the amount of charges accumulated at the lower electrodes 11 of each of the pixels 20, based on the electrical signal that has flowed in each of the signal lines 3. Image information is thereby obtained representing the image caused by the X-rays irradiated onto the radiation detector 10A.

Thus, according to the present exemplary embodiment, because the accumulated charges in the charge storage capacitors 5 of the pixels 20 are read out two lines at a time, the read-out speed of an image can be increased (in comparison to cases where read-out is one pixel line at a time). Consequently scan time can be made twice that when reading out one line at a time. The first exemplary embodiment therefore enables imaging at the high frame rates of video images.

Further, in the first exemplary embodiment, there is also one scan line 101 provided for each two lines of pixels. Therefore, the first exemplary embodiment can reduce the number of intersection locations of the scan lines 101 for a single signal line 3, and the line capacity of each signal line 3 can be made small. Accordingly, the first exemplary embodiment can therefore reduce the noise generated in the signal line 3. Moreover, the first exemplary embodiment can also increase the size of the pixels 20 by reducing the number of scan lines 101 provided.

Further, in the present exemplary embodiment, the two signal lines 3 along the column direction pixel lines each passes between the pixels 20 of alternate row direction pixel lines. Therefore, in the present exemplary embodiment, the line capacitances of odd and even signal lines 3 can be made substantially the same.

According to the present exemplary embodiment, because the signal lines 3 are disposed with a equally-spaced intervals, parasitic capacitances formed between each signal line 3 and others of the signal lines 3 can be reduced.

In the radiation detector 10A according to the first exemplary embodiment, the positions of the pixels 20 in alternate row direction pixel lines are shifted in the row direction by an amount corresponding to half the pixel width. Therefore, data from the pixels 20 of the pixel lines that are shifted in the row direction is data for positions that are shifted by half the pixel width from regular positions. However, data for regular positions may be generated by carrying out image processing at the signal processing device 106, such as, for example, interpolation or the like. Such image processing is exemplified in, for example, JP-A No. 2000-244733.

### Second Exemplary Embodiment

Next, as a second exemplary embodiment, a case in which the present invention is applied to a direct-conversion-type of radiation detector, which converts radiation directly to charges, is described.

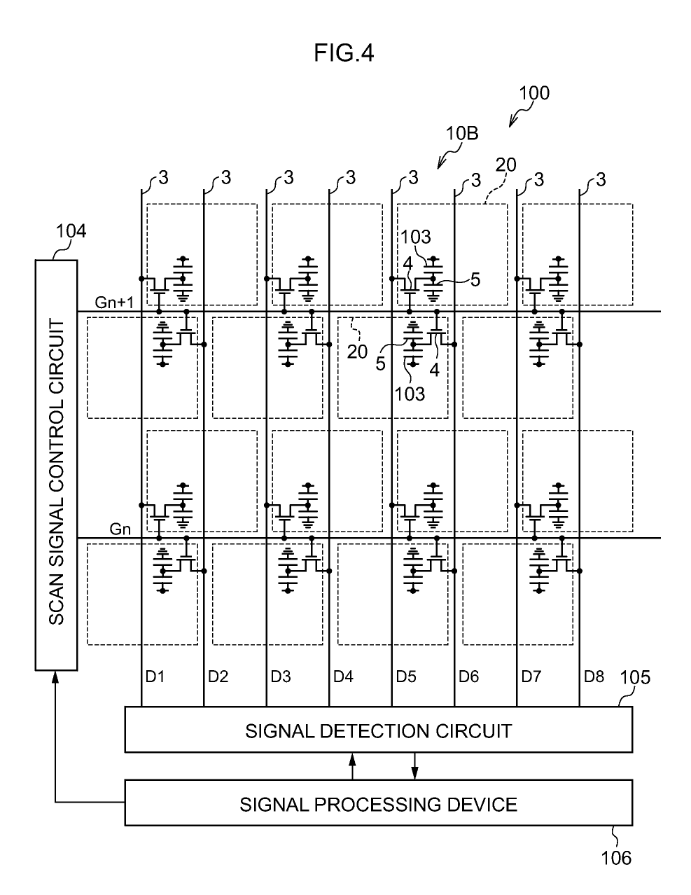

FIG. 4 illustrates the overall structure of the radiographic imaging device 100 that includes a radiation detector 10B according to the second exemplary embodiment. Herein, portions that correspond with the first exemplary embodiment described above (FIG. 1) are described with the same reference numerals as in the first exemplary embodiment.

In the radiation detector 10B, the plural pixels 20 are configured to include the sensor portions 103, the charge storage capacitors 5 and the TFT switches 4. The sensor portions 103 generate charges according to irradiation of radiation. The charge storage capacitors 5 accumulate the charges generated by the sensor portions 103. The TFT switches 4 read out the charges accumulated in the charge storage capacitors 5.

Similarly to the first exemplary embodiment, the pixels 20 are disposed in one direction (the horizontal direction of FIG. 4, which is hereinafter referred to as “the row direction”) and an intersecting direction relative to the row direction (the vertical direction in FIG. 4, which is hereinafter referred to as “the column direction”) forming a matrix. The pixels are plurally disposed with a subset of the row direction pixel lines in the matrix being shifted in the row direction. In the present exemplary embodiment, the pixels are arranged with the pixels 20 of every second row direction pixel line being shifted in the row direction by half of the pixel width (half the pitch) of the row direction pixel lines.

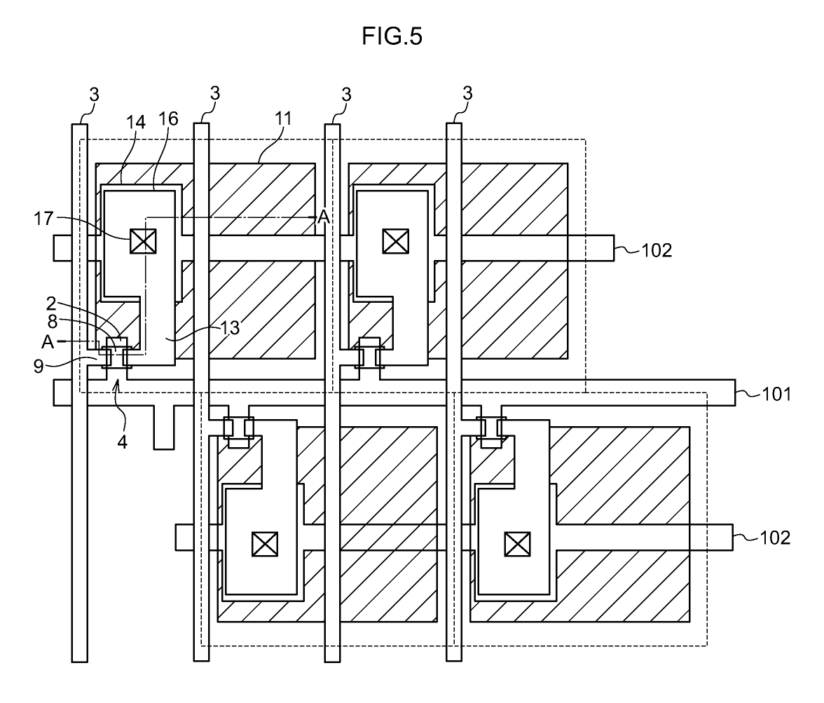

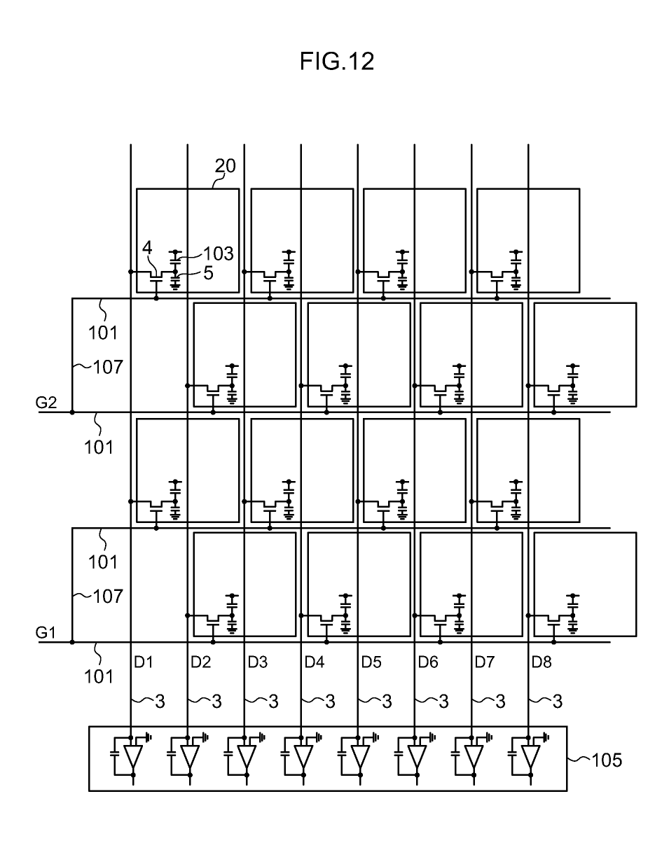

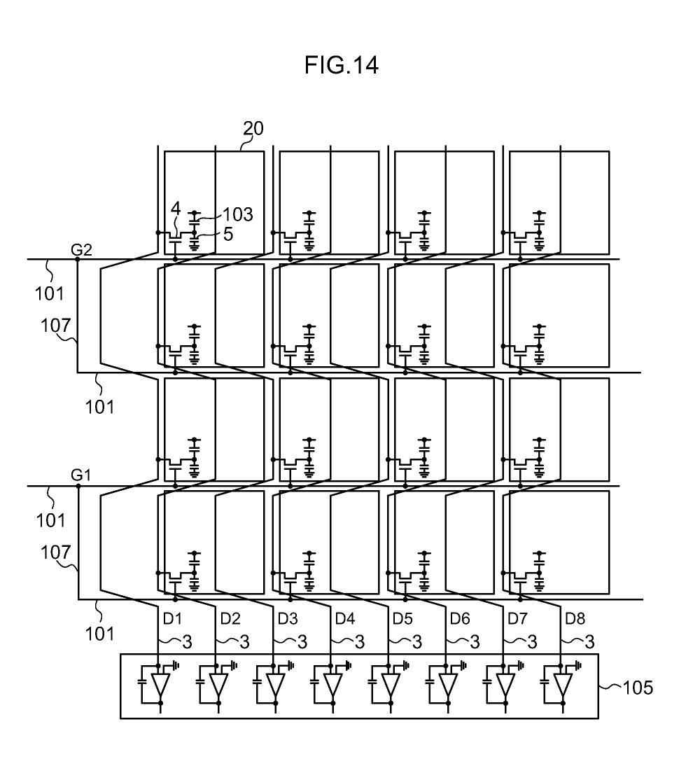

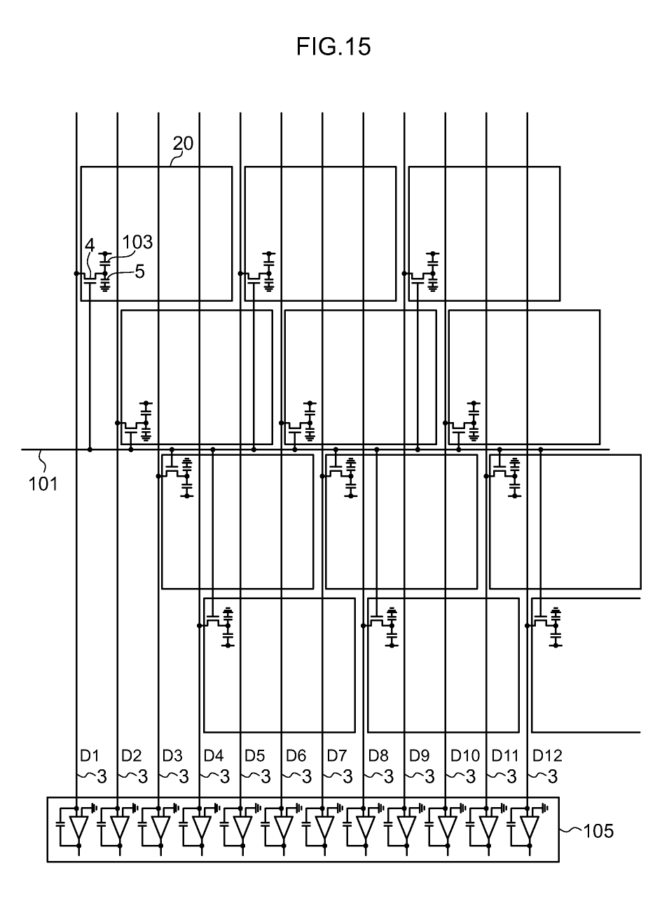

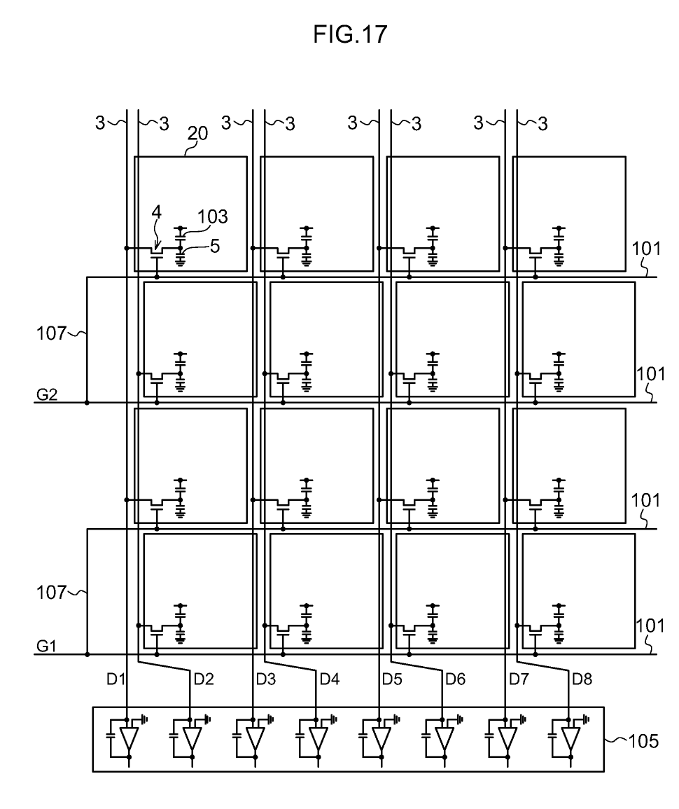

One electrode of each charge storage capacitor 5 is earthed via an auxiliary capacitor line 102 (FIG. 5), which is described later, and is set to ground level. In FIG. 4, and in the below-described FIG. 12, FIG. 14, FIG. 15 and FIG. 17, the one electrodes of the charge storage capacitors 5 are illustrated as being separately connected to ground.

In the radiation detector 10B, the scan lines 101 are provided one for each two row direction pixel lines in the matrix of the plural pixels 20, disposed between the two pixel lines. At each pixel 20, the TFT switch 4 is disposed at the respective scan line 101 side thereof. Each scan line 101 is connected to the TFT switches 4 provided in the pixels 20 of the two pixel lines, and switches these TFT switches 4.

In the radiation detector 10B, the signal lines 3 are disposed with equally-spaced intervals, two for each pixel line of the column direction pixel lines of the matrix array of the plural pixels 20. In the radiation detector 10B of the present exemplary embodiment, the pairs of signal lines 3 along the column direction pixel lines pass between the pixels 20 in alternate row direction pixel lines.

The signal lines 3 are connected to different TFT switches 4 that are connected to the same scan lines 101. Charges accumulated in the charge storage capacitors 5 flow into the signal lines 3 in accordance with switching states of the TFT switches 4. The signal detection circuit 105 is connected to the signal lines 3. The scan signal control circuit 104 is connected to the scan lines 101. The signal processing device 106 is connected to the signal detection circuit 105 and the scan signal control circuit 104.

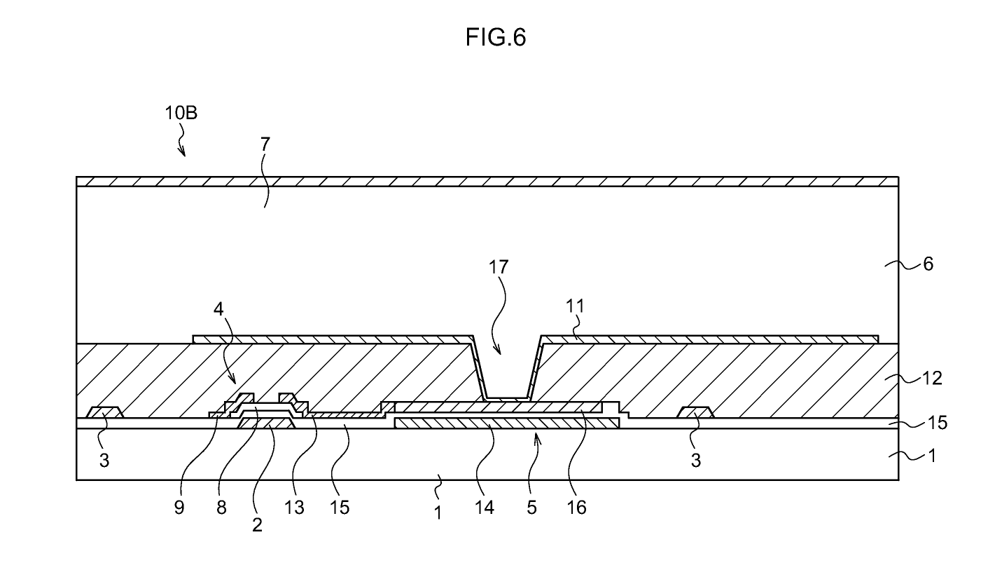

Next, the auxiliary capacitor lines 102 according to the present exemplary embodiment are described in more detail with reference to FIG. 5 and FIG. 6. FIG. 5 shows a plan view illustrating configuration of the radiation detector 10B according to the present exemplary embodiment. FIG. 6 shows a cross-sectional diagram taken along A-A of FIG. 5.

As illustrated in FIG. 6, in the radiation detector 10B, the scan lines 101 (see FIG. 5), storage capacitor lower electrodes 14, the gate electrodes 2 and the auxiliary capacitor lines 102 (see FIG. 5) are formed on the insulating substrate 1 as a first signal wiring layer. The gate electrodes 2 are connected to the scan lines 101, and the storage capacitor lower electrodes 14 are connected to the auxiliary capacitor lines 102.

The insulating layer 15 is formed over the scan lines 101, the storage capacitor lower electrodes 14, the gate electrodes 2 and the auxiliary capacitor lines 102. Portions of the insulating layer 15 that are disposed above the gate electrodes 2 act as the gate insulation film of the TFT switch 4.

The semiconductor active layer 8 is formed on the insulating layer 15 at positions that correspond to the gate electrodes 2.

On the above-mentioned layers, the source electrodes 9 and the drain electrodes 13 are formed as the second signal wiring layer. The signal lines 3 are formed together with the source electrodes 9 and the drain electrodes 13 in the wiring layer. Storage capacitor upper electrodes 16 are formed on the insulating layer 15 at positions that correspond with the storage capacitor lower electrodes 14. The source electrodes 9 are connected with the signal lines 3 (see FIG. 5), and the drain electrodes 13 are connected with the storage capacitor upper electrodes 16.

A contact layer (not illustrated) is formed between the source electrodes 9 and drain electrodes 13 and the semiconductor active layer 8. This contact layer is formed of an impurity doped semiconductor such as impurity doped amorphous silicon or the like. In the radiation detector 10B according to the present exemplary embodiment, the TFT switches 4 are configured by the gate electrodes 2, the insulating layer 15, the source electrodes 9, the drain electrodes 13 and a semiconductor layer 6. Further, in the radiation detector 10B according to the present exemplary embodiment, the charge storage capacitors 5 are configured by the storage capacitor lower electrodes 14, the insulating layer 15 and the storage capacitor upper electrodes 16. Note that, in the TFT switches 4, based on the polarity of charges that are collected and accumulated by charge storage capacitors 5, the source electrode 9 and the drain electrode 13 become opposite.

An interlayer insulating film 12 is formed covering the second signal wiring layer, over substantially the entire surface (substantially the whole region) where the pixels 20 are provided on the substrate 1. The contact holes 17 are formed at positions in the interlayer insulating film 12 that oppose the storage capacitor upper electrodes 16.

The lower electrodes 11 of the sensor portions 103 are formed on the interlayer insulating film 12 to cover the pixel region and fill in the contact hole 17 at each pixel 20. The lower electrodes 11 are formed of an amorphous transparent conductive/oxide film (ITO), and are connected with the storage capacitor upper electrodes 16 via the contact holes 17. Thus, the lower electrodes 11 and the TFT switches 4 are electrically connected via the storage capacitor upper electrodes 16.

The semiconductor layer 6 is uniformly formed over the lower electrodes 11 over substantially the whole area of the pixel region in which the pixels 20 are provided on the insulating substrate 1. The semiconductor layer 6 generates charges (electrons and holes) thereinside when radiation, such as x-rays or the like, is irradiated. Namely, the semiconductor layer 6 features conductivity and converts image information according to x-rays to charge information. The semiconductor layer 6 is formed of, for example, a-Se (amorphous selenium) with selenium as the principal component. Here, the meaning of the term “principal component” includes proportional content being at least 50%.

An upper electrode 7 is formed over the semiconductor layer 6. The upper electrode 7 is connected to a bias power supply (not illustrated), and provides a bias voltage from the bias power supply.

Next, operation of the radiographic imaging device 100 according to the present exemplary embodiment is briefly described.

When x-rays are irradiated onto the semiconductor layer 6 in the state in which the bias voltage is applied between the upper electrode 7 and the storage capacitor lower electrodes 14, charges (electron-hole pairs) are generated inside the semiconductor layer 6.

The semiconductor layer 6 and the charge storage capacitors 5 are electrically connected in series. Therefore, the electrons generated inside the semiconductor layer 6 migrate toward the positive electrodes and the holes migrate toward the negative electrode. During image detection, OFF signals are outputted from the scan signal control circuit 104 to all the scan lines 101, and negative bias is applied to the gate electrodes 2 of the TFT switches 4. Thus, the TFT switches 4 are held in OFF states. Therefore, the electrons generated inside the semiconductor layer 6 are collected by the lower electrodes 11 and are accumulated at the charge storage capacitors 5.

During image read-out, ON signals are outputted from the scan signal control circuit 104 to the scan lines 101 sequentially, one line at a time. Then, the ON signals (+10 to +20 V) are applied to the gate electrodes 2 of the TFT switches 4 sequentially via the scan lines 101. Accordingly, the TFT switches 4 of the pixels 20 of two lines at a time, in the row direction of the matrix of the plural pixels 20, are sequentially turned ON. Electronic signals corresponding to the charges accumulated in the charge storage capacitors 5 of the pixels 20 flow out into the signal lines 3, two lines at a time.

On the basis of the electronic signals that flow into the signal lines 3, the signal detection circuit 105 detects the charge amounts accumulated in the charge storage capacitors 5 of the sensor portions 103 as information of pixels corresponding to pairs of lines representing an image. Accordingly, the radiation detector 10B according to the present exemplary embodiment can obtain image information represented by the irradiated x-rays.

In the present exemplary embodiment, because the accumulated charges in the charge storage capacitors 5 of the pixels 20 are read out two lines at a time, the read-out speed of an image can be increased (in comparison to cases where read-out is one pixel line at a time). Consequently, in the radiation detector 10B according to the present exemplary embodiment, scan time can be made twice that when reading out one line at a time. The radiation detector 10B according to the present exemplary embodiment therefore enables imaging at the high frame rates of video images.

Further, in the present exemplary embodiment, there is also one scan line 101 provided for each two lines of pixels. Therefore, the present exemplary embodiment can reduce the number of intersection locations of the scan lines 101 for a single signal line 3, and the line capacity of each signal line 3 can be made small. Accordingly, the radiation detector 10B according to the present exemplary embodiment can therefore reduce the noise generated in the signal line 3. Moreover, the present exemplary embodiment can also increase the size of the pixels 20 by reducing the number of scan lines 101 provided.

Further, in the present exemplary embodiment, the two signal lines 3 along the column direction pixel lines each pass between the pixels 20 of alternate row direction pixel lines. Therefore, in the present exemplary embodiment, the line capacitances of odd and even signal lines 3 can be made substantially the same.

In the radiation detector 10B according to the second exemplary embodiment, the positions of the pixels 20 in alternate row direction pixel lines are disposed shifted in the row direction by an amount corresponding to half the pixel width. Therefore, data from the pixels 20 of the pixel lines that are shifted in the row direction is data for positions that are shifted by half the pixel width from regular positions. However, data for regular positions may be generated by carrying out image processing at the signal processing device 106, such as, for example, interpolation or the like.

### Third Exemplary Embodiment

Next, as a third exemplary embodiment, a case is described in which, in each pixel 20 of the direct conversion type radiation detector 10B, the TFT switch 4 and the charge storage capacitor 5 are separately disposed in two regions which are divided by the signal line 3 passing through a middle portion of the pixel 20.

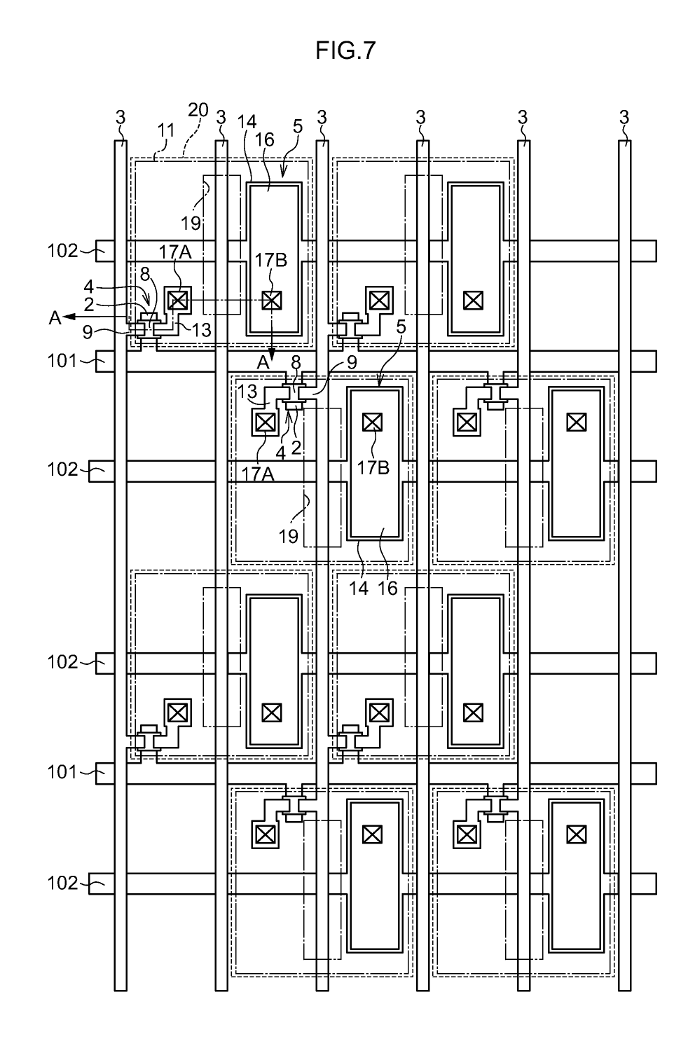

FIG. 7 shows a plan view illustrating structure of the radiation detector 10B according to the present exemplary embodiment. Herein, portions that are the same as in the second exemplary embodiment (see FIG. 5) are assigned with same reference numerals and description thereof will be omitted.

As illustrated in FIG. 7, in the radiation detector 10B, the TFT switch 4 and charge storage capacitor 5 at each pixel 20 are disposed separately in two regions which are divided by the signal line 3 passing through the middle portion of the pixel 20.

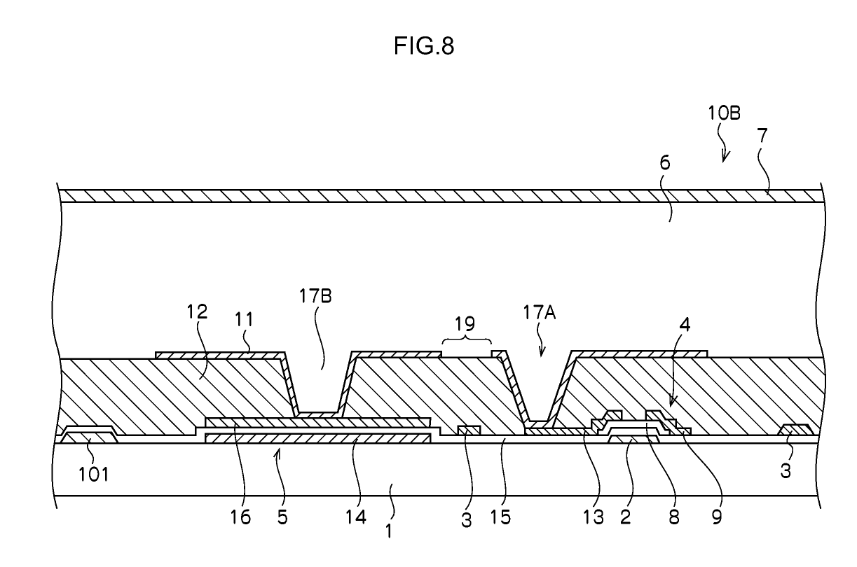

FIG. 8 shows a cross-sectional diagram taken along A-A of FIG. 7. Portions that are the same as in the second exemplary embodiment (see FIG. 6) are assigned the same reference numerals, and description thereof is omitted.

Contact holes 17A and 17B are formed in the interlayer insulating film 12 at positions facing the storage capacitor upper electrodes 16 and positions facing the drain electrodes 13, respectively.

The lower electrodes 11 at the respective pixels 20 are formed on the interlayer insulating film 12 to cover the pixel regions and fill in the contact holes 17A and 17B. The lower electrodes 11 are connected to the drain electrodes 13 via the contact holes 17A and are connected to the storage capacitor upper electrodes 16 via the contact holes 17B. Thus, the charge storage capacitors 5 and the TFT switches 4 are electrically connected via the lower electrodes 11. In addition, slits 19 are provided in the lower electrodes 11 at positions at which the signal lines 3 are disposed.

Thus, according to the present exemplary embodiment, because the charge storage capacitor 5 and the TFT switch 4 are separately disposed in two regions divided by the signal line 3, the region in which each is formed can be assured.

Furthermore, according to the present exemplary embodiment, the slits 19 are provided at positions of the lower electrodes 11, which collect the charges generated by the semiconductor layer 6, at which the signal lines 3 are provided. Therefore, the third exemplary embodiment can reduce parasitic capacitances that arise at the signal lines 3, between the signal lines 3 and the lower electrodes 11.

### Fourth Exemplary Embodiment

Next, as a fourth exemplary embodiment, a case is described in which, in the direct-conversion-type radiation detector 10B, each auxiliary capacitor line 102 is shared by plural pixel lines.

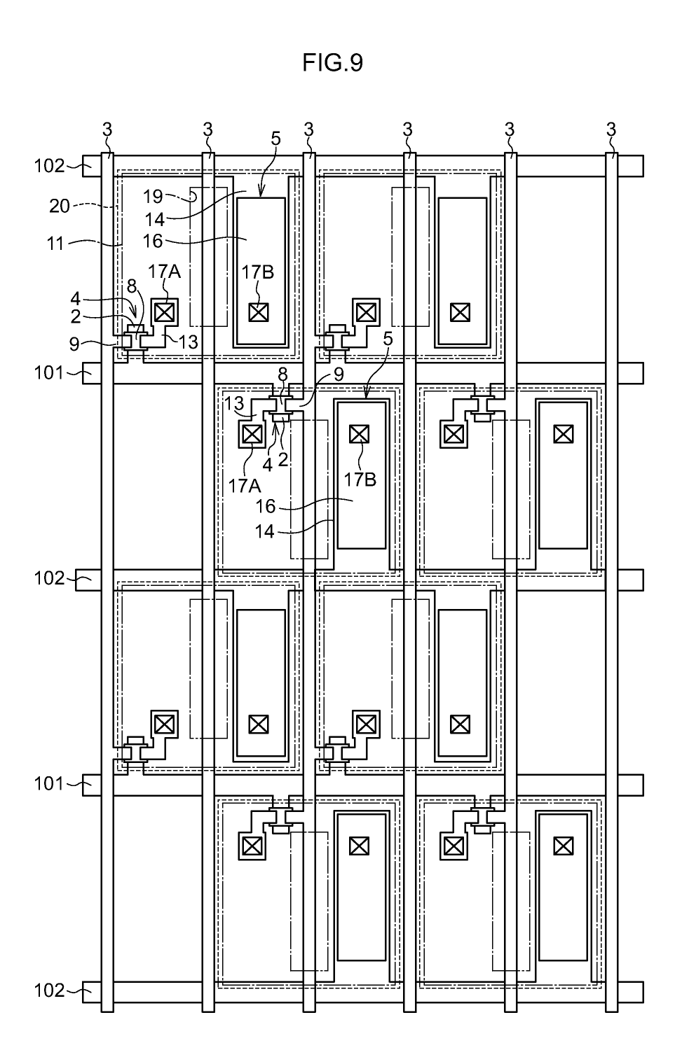

FIG. 9 shows a plan view illustrating the structure of the radiation detector 10B according to the present exemplary embodiment. Herein, portions that are the same as in the second and third exemplary embodiments (see FIG. 5 and FIG. 7) are assigned the same reference numerals and description thereof is omitted.

As illustrated in FIG. 9, in the radiation detector 10B, the auxiliary capacitor lines 102 are provided one for each two pixel lines of the row direction pixel lines of the matrix, and each auxiliary capacitor line 102 is disposed between the two pixel lines, intersecting across the scan lines 101. Each auxiliary capacitor line 102 is connected to the storage capacitor lower electrode 14 of the charge storage capacitor 5 provided at each pixel 20 of the two pixel lines.

Thus, according to the present exemplary embodiment, because the auxiliary capacitor lines 102 are provided one for each two lines, the number of intersection between the signal lines 3 and the auxiliary capacitor lines 102 is further reduced. Therefore, the fourth exemplary embodiment can reduce line capacitances of the signal lines 3.

Further, according to the present exemplary embodiment, because the number of auxiliary capacitor lines 102 is reduced, the size of the pixels 20 can be made larger.

### Fifth Exemplary Embodiment

Next, as a fifth exemplary embodiment, a case is described in which, in the direct-conversion-type radiation detector 10B, the auxiliary capacitor lines 102 are formed in the column direction.

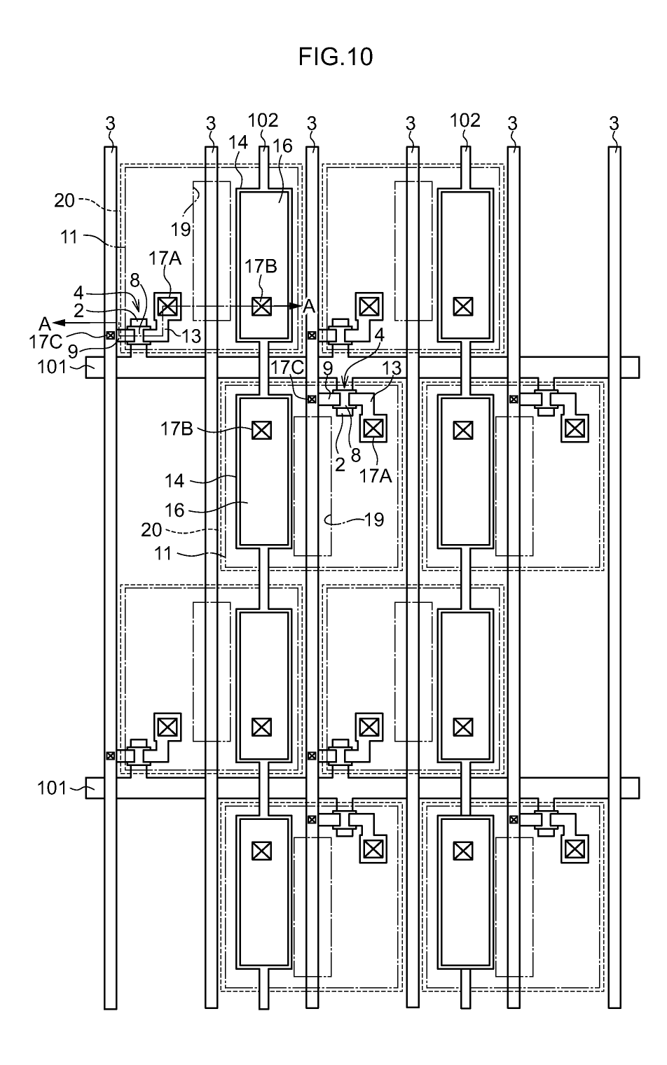

FIG. 10 shows a plan view illustrating structure of the radiation detector 10B according to the present exemplary embodiment. Herein, portions that are the same as in the second and third exemplary embodiments (see FIG. 5 and FIG. 7) are assigned the same reference numerals and description thereof is omitted.

As illustrated in FIG. 10, in the radiation detector 10B according to the present exemplary embodiment, the TFT switch 4 and charge storage capacitor 5 at each pixel 20 are disposed in two regions which are divided by the signal line 3 passing through a middle portion of the pixel 20. Thus, in the radiation detector 10B according to the present exemplary embodiment, the charge storage capacitors 5 are disposed in regions at sides of the pixels 20 that over laps in the column direction. Therefore, in the present exemplary embodiment, the regions in which the charge storage capacitors 5 are provided are serially lined up.

In the radiation detector 10B, the auxiliary capacitor lines 102 are provided one for each column direction pixel line of the matrix, and the auxiliary capacitor lines 102 are disposed side by side with the signal lines 3 passing through the regions in which the charge storage capacitors 5 are provided.

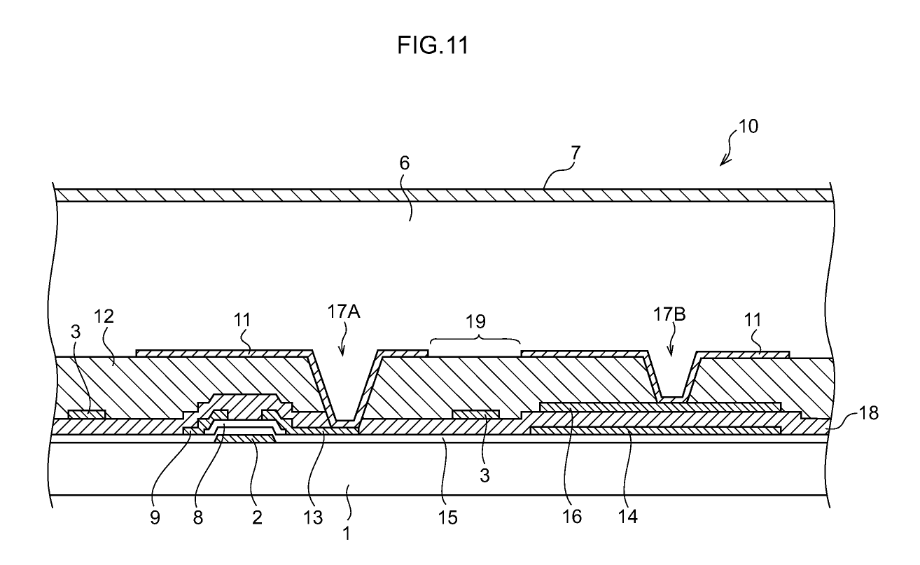

FIG. 11 shows a cross-sectional diagram taken along A-A of FIG. 10. Portions that are the same as in the second exemplary embodiment (see FIG. 6) are assigned the same reference numerals and description thereof is omitted.

In the radiation detector 10B according to the present exemplary embodiment, the scan lines 101 (see FIG. 10) and the gate electrodes 2 are formed on the insulating substrate 1 as the first signal wiring layer. Further, in the radiation detector 10B according to the present exemplary embodiment, the insulating layer 15 is formed over the first signal wiring layer. Furthermore, in the radiation detector 10B according to the present exemplary embodiment, the source electrodes 9, the drain electrodes 13, the storage capacitor lower electrodes 14 and the auxiliary capacitor lines 102 (see FIG. 10) are formed over the insulating layer 15 as the second signal wiring layer.

Each auxiliary capacitor line 102 is connected to the storage capacitor lower electrodes 14 of the charge storage capacitors 5 provided at the pixels 20 of the respective column direction pixel lines.

In the radiation detector 10B according to the present exemplary embodiment, an insulating film 18 is formed on the second signal wiring layer over substantially the whole region in which the pixels 20 are provided. The signal lines 3 are formed on the insulating film 18 as a third signal wiring layer, and the storage capacitor upper electrodes 16 are formed on the insulating film 18 at positions that correspond with the storage capacitor lower electrodes 14.

Contact holes 17C (see FIG. 10) are formed at positions of the insulating film 18 that correspond with the signal lines 3 and the source electrodes 9. The signal lines 3 and the source electrodes 9 are electrically connected via the contact holes 17C.

The interlayer insulating film 12 is formed on the third signal wiring layer over substantially the whole area thereof. The contact holes 17B are formed at positions of the interlayer insulating film 12 that correspond with the storage capacitor upper electrodes 16, and the contact holes 17A are formed at positions of the interlayer insulating film 12 and the insulating film 18 that correspond with the drain electrodes 13. The lower electrodes 11 formed on the interlayer insulating film 12 are connected with the drain electrodes 13 via the contact holes 17A, and are connected with the storage capacitor upper electrodes 16 via the contact holes 17B.

Thus, according to the present exemplary embodiment, because the auxiliary capacitor lines 102 are disposed in the column direction, there are no intersection between the signal lines 3 and the auxiliary capacitor lines 102. Therefore, the present exemplary embodiment can further reduce line capacitances of the signal lines 3.

### Sixth Exemplary Embodiment

Next, as a sixth exemplary embodiment, a case is described in which, the scan lines 101 are each provided at a row direction pixel line, sets of a plural number of the scan lines 101 are connected at periphery portions, and hence plural pixel lines are driven simultaneously. In the present exemplary embodiment, a mode of application to the direct-conversion-type radiation detector 10B is described, but the present exemplary embodiment may also be applied to the indirect-conversion-type radiation detector 10A.

FIG. 12 illustrates the overall structure of the radiation detector 10B according to the sixth exemplary embodiment. Herein, portions that are the same as in the second exemplary embodiment (see FIG. 4) are assigned the same reference numerals and description thereof is omitted.

As illustrated in FIG. 12, in the radiation detector 10B according to the present exemplary embodiment, the pixels 20 are plurally disposed in the matrix in the row direction and the column direction. In the radiation detector 10B according to the present exemplary embodiment, the pixels 20 are disposed with, in every second line of the row direction pixel lines, the pixels 20 in the row direction pixel line being shifted in the row direction by a unit of half the pixel width (half the pitch).

In the radiation detector 10B, the scan lines 101 are provided one for each of the row direction (the horizontal direction of FIG. 12) pixel lines of the matrix array of the plurally disposed pixels 20.

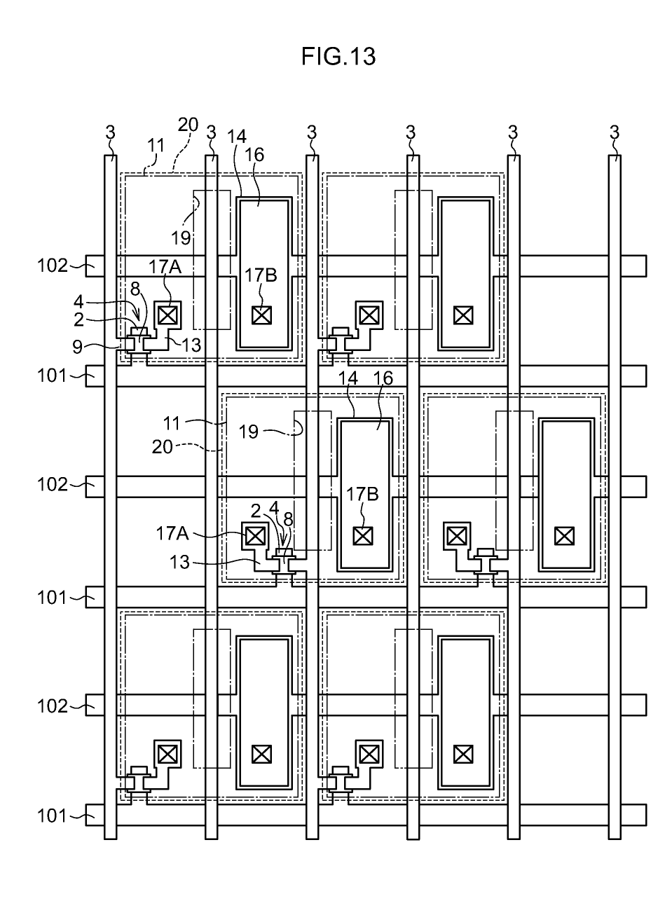

FIG. 13 shows a plan view illustrating structure of the radiation detector 10B according to the present exemplary embodiment. Herein, portions that are the same as in the second and third exemplary embodiments (see FIG. 5 and FIG. 7) are assigned the same reference numerals and description thereof is omitted.

As illustrated in FIG. 13, in the radiation detector 10B, the scan lines 101 are connected to the TFT switches 4 provided at the pixels 20 of the respective pixel lines, and switch the TFT switches 4.

As illustrated in FIG. 12, connection lines 107 are provided in the radiation detector 10B. Each connection line 107 electrically connects a pair of the scan lines 101. One of the pair of scan lines 101 connected by each connection line 107 is connected to the scan signal control circuit 104.

Therefore, when an ON signal is outputted from the scan signal control circuit 104 to the scan lines 101, the ON signal flows into two scan lines 101 that are connected by a connection line 107.

During image read-out, the scan signal control circuit 104 outputs ON signals to the scan lines 101 in sequence. Therefore, the ON signals are supplied to the pairs of the scan lines 101 and charges are read out two lines at a time.

Thus, according to the present exemplary embodiment, because the charges accumulated at the charge storage capacitors 5 of the pixels 20 are read out two lines at a time, the read-out speed of an image is increased (in comparison to cases where read-out is one pixel line at a time).

### Seventh Exemplary Embodiment

Next, as a seventh exemplary embodiment, a case is described in which it is the signal lines 3 that are shifted in the row direction at a subset of the row direction pixel lines. In the present exemplary embodiment, a mode of application to the direct-conversion-type radiation detector 10B is described, but the present exemplary embodiment may also be applied to the indirect-conversion-type radiation detector 10A.

FIG. 14 illustrates overall structure of the radiation detector 10B according to the seventh exemplary embodiment. Portions that are the same as in the second and sixth exemplary embodiments (see FIG. 4 and FIG. 12) are assigned the same reference numerals and description thereof is omitted.

As illustrated in FIG. 14, in the radiation detector 10B according to the present exemplary embodiment, the pixels 20 are plurally disposed in the matrix in the row direction and the column direction.

In this radiation detector 10B, the scan lines 101 are provided one for each line of pixels in the row direction (the horizontal direction of FIG. 14) of the matrix array of the plurally disposed pixels 20.

In the radiation detector 10B, the connection lines 107 electrically connecting pairs of the scan lines 101 are provided at peripheral portions. One of each pair of scan lines 101 connected by a connection line 107 is connected to the scan signal control circuit 104.

Therefore, when an ON signal is outputted from the scan signal control circuit 104 to the scan lines 101, the ON signal flows into two scan lines 101 that are connected by a connection line 107.

In the radiation detector 10B, the signal lines 3 are disposed with equally-spaced intervals, in sets of two for each of the column direction pixel lines of the matrix array of the plurally disposed pixels 20. The signal lines 3 are disposed shifted in the row direction by an amount corresponding to half the pixel width (half the pitch) at alternate row direction pixel lines. Thus, alternately at each row direction pixel line, of each pair of signal lines 3, one signal line 3 passes through a middle portion of a pixel 20 and the other signal line 3 passes between two pixels 20.

During image read-out, the scan signal control circuit 104 outputs ON signals to the scan lines 101 in sequence. Thus, the ON signals are supplied to the pairs of the scan lines 101 and charges are read out two lines at a time.

Thus, according to the present exemplary embodiment, because the charges accumulated at the charge storage capacitors 5 of the pixels 20 are read out two lines at a time, the read-out speed of an image is increased relative to a case in which charges are read out one line at a time (in comparison to cases where read-out is one pixel line at a time).

Further, the pairs of signal lines 3 along the column direction pixel lines pass between the pixels 20 of alternate row direction pixel lines. Therefore, in the present exemplary embodiment, the line capacitances of odd and even signal lines 3 may be substantially the same.

In the radiation detector 10B according to the seventh exemplary embodiment, the positions of the pixels 20 are not shifted as in the first to sixth exemplary embodiments. Therefore, in the radiation detector 10B according to the seventh exemplary embodiment, data from the pixels 20 is data of regular positions. Therefore, image processing such as interpolation or the like is not required.

Now, in the exemplary embodiments described above, cases in which the scan lines 101 are disposed in the row direction of the matrix array of the plurally provided pixels 20 and the signal lines 3 are disposed in the column direction, was described. However, the present invention is not to be limited thereto. In an alternative exemplary embodiment, the scan lines 101 may be disposed in the column direction and the signal lines 3 may be disposed in the row direction.

Furthermore, in the first to fifth exemplary embodiments, cases in which the scan lines 101 are provided one for each two row direction pixel lines, and the signal lines 3 are provided two for each column direction pixel line, was described. However, the present invention is not to be limited thereto. For example, in an alternative exemplary embodiment, the scan lines 101 may be provided one for each of N row direction pixel lines (where N is a natural number that is 2 or greater), and the signal lines 3 may be provided N for each column direction pixel line. If the scan lines 101 are provided one for each three row direction pixel lines, the layer structure of the radiation detector 10A or 10B may be, for example, the layer structure as in the fifth exemplary embodiment, with wiring that connects the scan lines 101 with the gate electrodes 2 being formed in the first signal wiring layer. FIG. 15 illustrates the radiation detector 10B according to an alternative exemplary embodiment, in which the pixels 20 of the row direction pixel lines are disposed to be shifted in the row direction between each pixel line by an amount corresponding to a quarter of the width of the pixels (quarter of the pitch), the scan lines 101 are provided one for each four row direction pixel lines, and the signal lines 3 are provided uniformly, in sets of four for each column direction pixel line.

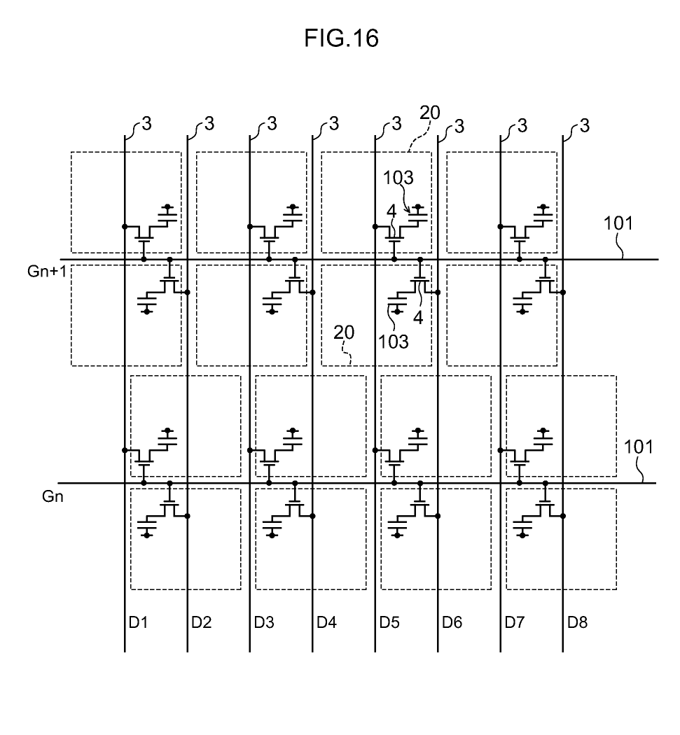

In the first to sixth exemplary embodiments described above, cases in which the pixels 20 in the row direction pixel lines are disposed to be shifted in the row direction between each line, was described. However, the present invention is not to be limited thereto. For example, in an alternative exemplary embodiment, the pixels 20 of a plural number of pixel lines may be shifted in the row direction in sets of the plural number of row direction pixel lines. FIG. 16 illustrates the radiation detector 10B according to an alternative exemplary embodiment, in which the pixels 20 are shifted in the row direction in sets of two pixel lines that are connected to the same scan line 101.

In the sixth and seventh exemplary embodiments described above, cases in which the scan lines 101 are provided one for each row direction pixel line and pairs of the scan lines 101 are electrically connected by the connection lines 107, was described. However, the present invention is not to be limited thereto. In an alternative exemplary embodiment, sets of N of the scan lines 101 may be electrically connected by the connection lines 107.

In the first to sixth exemplary embodiments described above, cases in which the pixels 20 are shifted in the row direction at each row direction pixel line, and in the seventh exemplary embodiment described above, the positions of the signal lines 3 are shifted in the row direction at each row direction pixel line, was described. However, the present invention is not to be limited thereto. For example, the positions of the pixels 20 and the signal lines 3 may both be shifted in the row direction, such that the signal wiring provided for each column direction pixel line is disposed between the pixels 20 of some of the row direction pixel lines.

In the first to sixth exemplary embodiments described above, cases in which the signal lines 3 are disposed with equally-spaced intervals, two for each column direction pixel line, and the pixels 20 are shifted in the row direction by half the pixel width between each row direction pixel line, was described. However, the present invention is not to be limited thereto. For example, in an alternative exemplary embodiment, as illustrated in FIG. 17, the signal lines 3 may be disposed non-uniformly so as to run along the edges of the pixels 20 of the pixel lines. In this case, the row direction pixel lines may be shifted in the row direction by an amount corresponding to the width of a pair of the signal lines 3 at alternate row direction pixel lines.

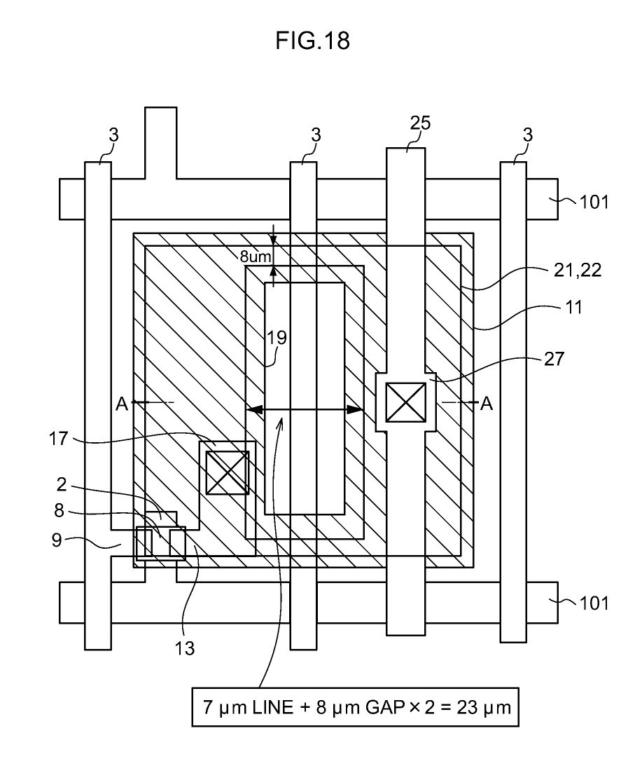

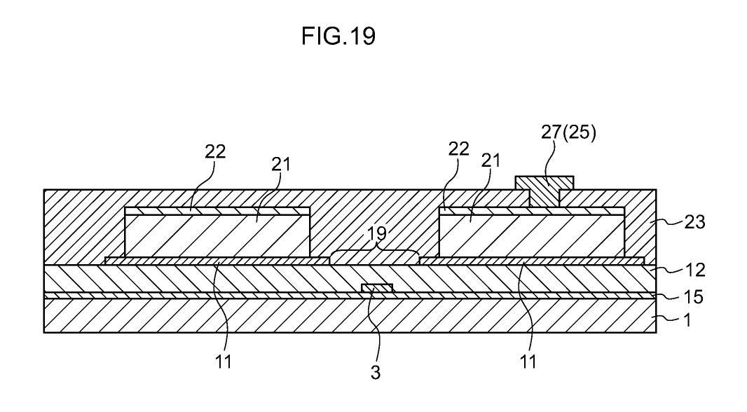

In the third exemplary embodiment described above, a case in which, in the direct conversion type of radiation detector 10B, the slits 19 are provided at positions of the lower electrodes 11 at which the signal lines 3 are disposed, was described. However, the present invention is not to be limited thereto. FIG. 18 illustrates a case in which, in the indirect conversion type of radiation detector 10A, the slits 19 are provided at positions of the sensor portions 103 (the lower electrodes 11, the semiconductor layers 21 and the upper electrodes 22) at which the signal lines 3 are disposed. FIG. 19 illustrates a diagrammatic sectional diagram taken along A-A of FIG. 18. Thus, because the slits 19 are provided, an alternative exemplary embodiment may reduce parasitic capacitances that arise at the signal lines 3, between the signal lines 3 and the lower electrodes 11, and differences in line capacitance between the signal lines 3 may be kept small. If the size of each pixel 20 is 100 μm×100 μm, the width of all lines is 7 μm, and gaps between the lines and the semiconductor layers 21 are 8 μm, then if the slits 19 are not provided, each pixel 20 has an effective pixel area of 5,929 μm² (=100−7+8×2))², and the area of the pixel 20 is 10,000 μm² (=100 μm×100 μm). Therefore, the fill factor is 59.3% (=5,929/10,000). In contrast, if the slits 19 are provided, the effective pixel area of each pixel 20 is 5,929−23×(100−7+8×2))=4,185 μm². Therefore, the fill factor is 41.9% (=4,185/10,000).

In the exemplary embodiments described above, cases in which the pixels 20 are plurally provided in a matrix with the image detection area being a single pixel area, and are read out, was described. However, for example, in an alternative exemplary embodiment, an image detection area may be divided into plural pixel areas as in JP-A No. 2003-264273 and a configuration as in the above exemplary embodiments applied to the configuration of each pixel area. When pixels are read out by the pixel areas, a video image may be imaged at an even higher frame rate.

In the exemplary embodiments described above, cases in which the present invention is applied to the radiographic imaging device 100 that detects an image by detecting x-rays that serve as the radiation that is the object of detection, was described. However, the present invention is not to be limited thereto. For example, the radiation that is the object of detection may be any of gamma rays, visible light, ultraviolet light, infrared light and the like.

In the radiation detector 10A of the exemplary embodiments described above, the charge storage capacitors 5 may be formed at the pixels 20. In the exemplary embodiments described above, cases are described in which, in the radiation detector 10B, the charge storage capacitors 5 are provided at the pixels 20. However, for example, if the lower electrodes 11 have capacitances capable of satisfactorily accumulating charges, the charge storage capacitors 5 need not be formed at the pixels 20.

The structure of the radiographic imaging device 100 and the structures of the radiation detector 10A and 10B described in the above exemplary embodiments are examples and may be suitably modified within a scope not departing from the spirit of the present invention.

What is claimed is:

1. A radiation detector comprising:
a plurality of pixels disposed in a matrix, along a first direction and a second direction intersecting with the first direction, each pixel accumulates charges generated by the irradiation of radiation, and includes a switching element for reading out the accumulated charges;
scan lines that switch each of the switching elements, each scan line disposed corresponding to a plurality of pixel lines in the first direction, and connected to each of the switching element provided at the respective pixels in the plurality of pixel lines; and
signal lines, in which a plurality of signal lines are disposed corresponding to each of the pixel lines in the second direction, each signal line of the signal lines disposed corresponding to the same pixel line connected to a different switching element of the switching elements connected to the same scan line, and charges accumulated in the pixels flowing through the signal lines according to switching state of the switching elements,
wherein at least one of the pixel lines and the signal lines is disposed shifted in the first direction at a subset of the pixel lines in the first direction, such that the plurality of signal lines provided for each pixel line in the second direction are disposed between pixels of the pixel lines in the first direction.

2. The radiation detector according to claim 1, wherein:
the scan lines are provided such that one scan line is provided for each two pixel lines in the first direction, disposed between the two respective pixel lines; and
each of the switching elements is provided at the scan line side of the corresponding pixel.

3. The radiation detector according to claim 1, wherein two of the signal lines are provided for each of the pixel lines in the second direction, with one of the two signal lines disposed so as to pass through a central portion of the pixels with equally-spaced intervals.

4. The radiation detector according to claim 1, wherein:
the signal lines are provided with equally-spaced intervals; and
at each pixel line in the first direction, the pixels of the pixel line in the first direction are disposed shifted in the first direction by an amount corresponding to the spacing of the signal lines in the first direction.

5. The radiation detector according to claim 1, wherein:
the pixels are further provided with a collection electrode that collects generated charges, and
the collection electrode is provided with a slit at a position where the signal line is disposed.

6. The radiation detector according to claim 5, wherein:
the pixels are further provided with a charge accumulation portion that accumulates the collected charges, and
the charge accumulation portion and the switching elements are electrically connected via the collection electrodes.

7. The radiation detector according to claim 6, wherein the charge accumulation portions is configured with two facing electrodes, and
further including auxiliary capacitor lines, each disposed to a plurality of pixel lines in the first direction, each connected to one of the electrodes of the charge accumulation portion provided at each of the pixels of the plurality of pixel lines.

8. The radiation detector according to claim 6, wherein the charge accumulation portion is configured with two facing electrodes, and
further including auxiliary capacitor lines, each disposed corresponding to each of the pixel lines in the second direction alongside the signal lines, and each connected to one of the electrodes of the charge accumulation portions provided at each of the pixels in each of the pixel lines in the second direction.

9. The radiation detector according to claim 7, wherein the signal lines and the auxiliary capacitor lines are formed in different wiring layers.

10. A radiation detector comprising:
a plurality of pixels disposed in a matrix, along a first direction and a second direction intersecting with the first direction, each pixel accumulates charges generated by the irradiation of radiation, and includes a switching element for reading out the accumulated charges;
scan lines that switch each of the switching elements, one scan line being disposed corresponding to each pixel line in the first direction, the scan lines being connected to each of the switching elements provided to each pixel in the corresponding of pixel line;
connection lines, each electrically connecting a specific number of the scan lines; and
signal lines, in which a plurality of signal lines are disposed corresponding to each of the pixel lines in the second direction, each signal line of the signal lines disposed corresponding to the same pixel line being connected to a different switching elements of the switching elements connected to the specific number of scan lines electrically connected by the same connection line, and the charges accumulated at the pixels flow through the signal lines according to the switching state of the switching elements,
wherein at least one of the pixel lines and the signal lines is disposed shifted in the first direction at a subset of the pixel lines in the first direction, such that the plurality of signal lines provided for each pixel line in the second direction are disposed between pixels of the pixel lines in the first direction.

11. The radiation detector according to claim 10, wherein two of the signal lines are provided for each of the pixel lines in the second direction, with one of the two signal lines disposed so as to pass through a central portion of the pixels with equally-spaced intervals.

12. The radiation detector according to claim 10, wherein:
the signal lines are provided with equally-spaced intervals; and
at each pixel line in the first direction, the pixels of the pixel line in the first direction are disposed shifted in the first direction by an amount corresponding to the spacing of the signal lines in the first direction.

13. The radiation detector according to claim 10, wherein:
the pixels are further provided with a collection electrode that collects generated charges, and
the collection electrode is provided with a slit at a position where the signal line is disposed.

14. The radiation detector according to claim 13, wherein:
the pixels are further provided with a charge accumulation portion that accumulates the collected charges, and
the charge accumulation portion and the switching element are electrically connected via the collection electrodes.

15. The radiation detector according to claim 14, wherein the charge accumulation portions is configured with two facing electrodes, and
further including auxiliary capacitor lines, each disposed corresponding to each of a plurality of pixel lines in the first direction, each connected to one of the electrodes of the charge accumulation portion provided at each of the pixels of the plurality of pixel lines.

16. The radiation detector according to claim 14, wherein the charge accumulation portion is configured with two facing electrodes, and
further including auxiliary capacitor lines, each disposed corresponding to each of the pixel lines in the second direction alongside the signal lines, and each connected to one of the electrodes of the charge accumulation portions provided at each of the pixels in each of the pixel lines in the second direction.

17. The radiation detector according to claim 15, wherein the signal lines and the auxiliary capacitor lines are formed in different wiring layers.
